(19) United States
(12) Patent Application Publication
(10) Pub. No.: US 2004/0228704 A1
(43) Pub. Date: Nov. 18, 2004

(54) Fastener system

(76) Inventor: Dov Rotshtain, Netanya (IL)

Correspondence Address: Dekel Patent Ltd., Beit HaRofim, Room 27, 18 Menuha VeNahala Street, Rehovot, 76209, IL

(21) Appl. No.: 10/872,409

(22) Filed: Jun. 22, 2004

Related U.S. Application Data
(63) Continuation-in-part of application No. 10/232,384, filed on Sep. 3, 2002.

(30) Foreign Application Priority Data
Apr. 30, 2001 (IL) 142868

(51) Int. Cl. F16B 23/00

(52) U.S. Cl. 411/408

(57) ABSTRACT

A fastening system including a connector element including a conical head portion from which extends a threaded shank, a hole being formed through the head portion and the shank, the head portion being resiliently squeezable in a generally radially inwards direction, the hole being adapted for an elongate element to passes therethrough, a sleeve member formed with a countersunk aperture, an outer surface of the sleeve member being formed with anchoring protrusions, and a threaded nut element threadedly fastened to the threaded shank, wherein tightening of the threaded nut element moves and wedges the conical head portion against the countersunk aperture and squeezes the head portion radially inwards. Examples of articles constructed with the fastening system are shown and described.

### FIELD OF THE INVENTION

The present invention relates generally to fastener systems, and particularly to a system and method for fastening elongate elements, such as rods, to planar elements, such as plates.

### BACKGROUND OF THE INVENTION

Many kinds of mechanical fasteners are known for assembling shelves, desks, beds and the like. Besides the familiar nuts, bolts, screws, nails and rivets, there are different kinds of connectors for making all kinds of constructions from metal, plastic, wood, glass and the like. However, it is not easy to fasten certain structural elements made of different materials to one another. For example, it is not an easy task to fasten metal rods to glass plate, without the fastener inflicting damage to one of the parts. Furthermore, it is not a straightforward task to make the connection adjustable along any length of the rods.

### SUMMARY OF THE INVENTION

The present invention seeks to provide an improved fastening system that is suited for fastening for elongate elements, such as rods, to planar elements, such as plates. The connection is easily and quickly adjustable along any length of the elongate elements, yet is very strong and reliable.

It is noted that throughout the specification and claims the term “elongate element” encompasses any elongate structural member, such as a bar, rod, pole, wire and the like, of any size or diameter.

There is thus provided in accordance with an embodiment of the present invention a fastening system including a connector element including a conical head portion from which extends a threaded shank, a hole being formed through the head portion and the shank, the head portion being resiliently squeezable in a generally radially inwards direction, the hole being adapted for an elongate element to passes therethrough, a sleeve member formed with a countersunk aperture, an outer surface of the sleeve member being formed with anchoring protrusions, and a threaded nut element threadedly fastened to the threaded shank, wherein tightening of the threaded nut element moves and wedges the conical head portion against the countersunk aperture and squeezes the head portion radially inwards.

In accordance with an embodiment of the present invention the anchoring protrusions may protrude non-perpendicularly from the outer surface of the sleeve member.

Further in accordance with an embodiment of the present invention one face of the sleeve member may include a rim with an outer diameter greater than that of a body of the sleeve member. An elongate element may pass through the hole, wherein tightening of the threaded nut element moves and wedges the conical head portion against the countersunk aperture and squeezes the head portion radially inward against the elongate element. The sleeve member may be received in a hole formed in a planar element, and the anchoring protrusions may anchor against the hole formed in the planar element.

In accordance with an embodiment of the present invention the head portion may be formed with slits that define petal portions, the petal portions being resiliently squeezable in a generally radially inwards direction. The connector element may be formed with at least one lengthwise axial cut extending from a periphery of the head portion and the shank at least partially through to the hole.

Examples of articles constructed with the fastening system are shown hereinbelow.

### BRIEF DESCRIPTION OF THE DRAWINGS

The present invention will be understood and appreciated more fully from the following detailed description taken in conjunction with the drawings in which:

FIG. 1 is a simplified, partially sectional illustration of a fastening system, constructed and operative in accordance with an embodiment of the present invention; and

FIGS. 2A and 2B are simplified side-view and top-view, partially sectional illustrations, respectively, of a connector element of the fastening system of FIG. 1;

FIG. 2C is a simplified illustration of a connector element of the fastening system of FIG. 1 with a lengthwise axial cut, in accordance with an embodiment of the present invention;

FIG. 3 is a simplified, partially sectional illustration of the fastening system of FIG. 1, constructed and operative in accordance with another embodiment of the present invention;

FIG. 4 is a simplified, partially sectional illustration of the fastening system of FIG. 1, constructed and operative in accordance with yet another embodiment of the present invention;

FIGS. 5A-5E are simplified illustrations of examples of articles constructed with the fastening system of the present invention; and

FIG. 6 is a simplified illustration of the fastening system of FIG. 1, constructed and operative in accordance with still another embodiment of the present invention.

### DETAILED DESCRIPTION OF EMBODIMENTS

Reference is now made to FIG. 1, which illustrates a fastening system 10, constructed and operative in accordance with a preferred embodiment of the present invention.

Fastening system 10 preferably includes a connector element 12 comprising a conical head portion 14 from which extends a threaded shank 16. A hole 18 is preferably formed through head portion 14 and shank 16. Head portion 14 is resiliently squeezable in a generally radially inwards direction, as indicated by arrows 19. Accordingly head portion 14 may be constructed of a sufficiently flexible plastic or similar material.

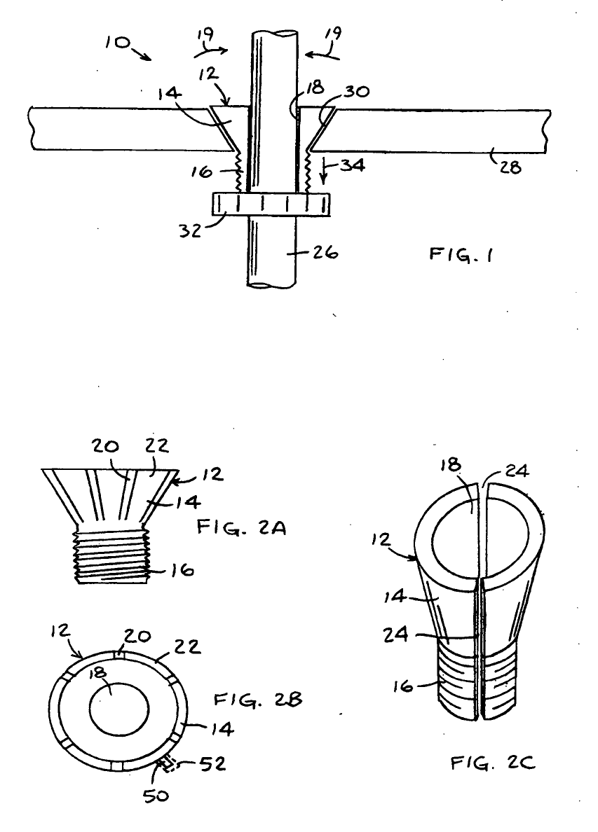

Referring additionally to FIGS. 2A and 2B, head portion 14 may be formed with slits 20 that define petal portions 22. Petal portions 22 are resiliently squeezable in the generally radially inwards direction.

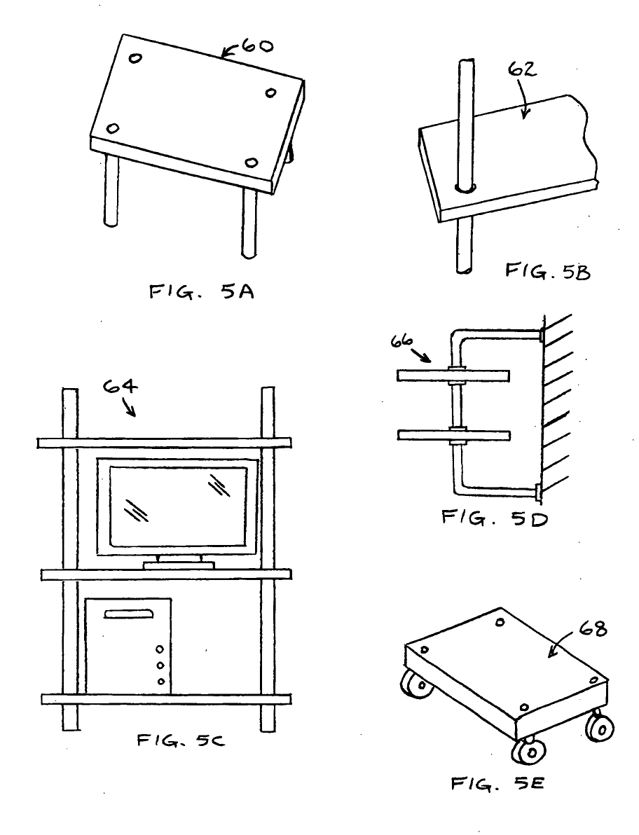

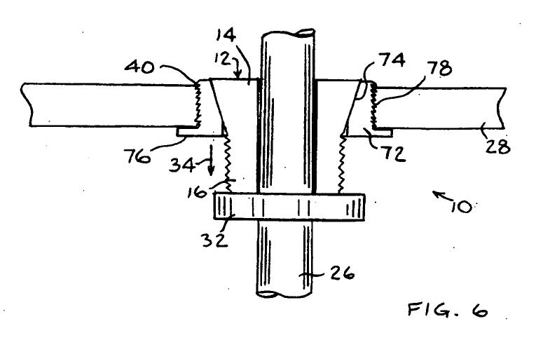

In FIGS. 2A and 2B, shank 16 has a contiguous perimeter. An alternate construction is shown in FIG. 2C, wherein connector element 12 is formed with one or more lengthwise axial cuts 24 extending from a periphery of head portion 14 and shank 16 at least partially through to hole 18. FIG. 2C shows an embodiment wherein two axial cuts 24 are cut completely through to hole 18, thereby cutting connector element 12 into two halves. This permits slipping connector element 12 over curved rods, pipes and the like (such as in the shower apparatus of FIG. 5D).

Reference is now made again to FIG. 1, which illustrates a possible construction that may be made with fastening system 10. An elongate element 26, such as, but not limited to, a metal, plastic or wooden rod, for example, passes through hole 18. A planar element 28, such as, but not limited to, a metal, plastic or glass plate, or a wall, for example, is formed with a countersunk aperture 30. The conical head portion 14 is received in countersunk aperture 30. A threaded nut element 32 is threadedly fastened to shank 16. Tightening nut element 32 causes connector element to advance generally in the direction of an arrow 34, thereby fixedly wedging head portion 14 in countersunk aperture 30, and fixedly squeezing head portion 14 against elongate element 26. This forms a secure connection between elongate element 26 and planar element 28.

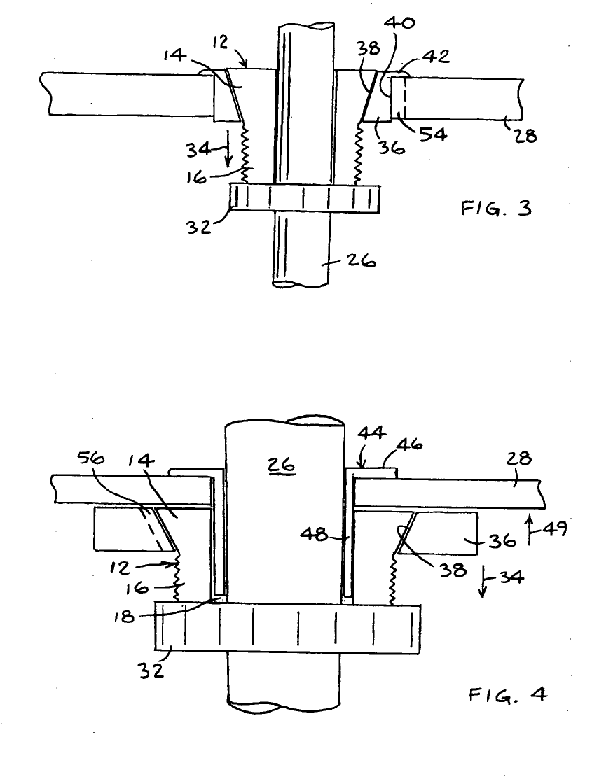

Reference is now made to FIG. 3, which illustrates the fastening system 10, constructed and operative in accordance with another embodiment of the present invention. In this embodiment, a conical sleeve member 36 is provided, formed with a countersunk or chamfered aperture 38. Sleeve member 36 is received in an aperture 40 formed in planar element 28, and may have a rim 42 that overlaps a surface of planar element 28. Conical head portion 14 is received in countersunk aperture 38 of sleeve member 36. As similarly described hereinabove, tightening nut element 32 causes connector element to advance generally in the direction of arrow 34, thereby fixedly wedging head portion 14 in countersunk aperture 38 and sleeve member 36 in aperture 40 of planar element 28, and fixedly squeezing head portion 14 against elongate element 26. This forms a secure connection between elongate element 26 and planar element 28. Sleeve member 36 acts as a protective washer for the connection to planar element 28.

Reference is now made to FIG. 4, which illustrates the fastening system 10, constructed and operative in accordance with yet another embodiment of the present invention. In this embodiment, a washer member 44 is provided, comprising a rim portion 46 extending from a hollow body portion 48. The body portion 48 is received in hole 18 of connector element 12, and elongate element 26 passes through body portion 48. The planar element 28 is intermediate rim portion 46 and sleeve member 36. As similarly described hereinabove, tightening nut element 32 causes connector element to advance generally in the direction of arrow 34, thereby fixedly wedging head portion 14 in countersunk aperture 38, and fixedly squeezing head portion 14 against body portion 48 and elongate element 26. The tightening action also causes sleeve member 36 to move against planar element 28, generally in the direction of an arrow 49, thereby trapping planar element 28 between rim portion 46 and sleeve member 36. This forms a secure connection between elongate element 26 and planar element 28. Sleeve member 36 and washer member 44 serve as protective elements for the connection to planar element 28, which may be particularly effective for connecting metal rods to glass plates, for example.

Any combination of the elements of fastening system 10 may comprise an anti-rotation connection. For example, as seen in FIG. 2A, planar element 28 and connector element 12 may comprise a tongue-in-groove connection, such as a tongue 50 protruding from one of the petals 22 that is received in a groove 52 formed in planar element 28. Similarly, as seen in FIG. 3, connector element 12 and sleeve member 36, or sleeve member 36 and planar element 28, may comprise a tongue-in-groove connection 54. The same may hold true for any combination of at least two of planar element 28, connector element 12, sleeve member 36 and washer member 44, which may comprise a tongue-in-groove connection 56, as seen in FIG. 4.

One of the advantages of the fastening system 10 of the present invention is that one can easily adjust or set the height of elongate element 26 with respect to planar element 28 at any point. For example, planar element 28 may be a shelf and elongate element 26 may be a pole for a set of shelves. The shelves may be placed at any arbitrary height. This is in contrast to the prior art, wherein the shelves may be placed generally only at preset discrete points.

Reference is now made to FIGS. 5A-5E, which illustrate examples of articles that may be constructed with fastening system 10 of the present invention, such as, but not limited to, a table 60, shelf 62, furniture 64, shower apparatus 66, and wagon 68.

Reference is now made to FIG. 6, which illustrates the fastening system 10, constructed and operative in accordance with still another embodiment of the present invention. In this embodiment, a sleeve member 72 is provided, formed with a countersunk (or chamfered or conical, all the terms being used interchangeably) aperture 74. One face of sleeve member 72 may include a rim 76 with an outer diameter greater than that of the body of sleeve member 72. An outer surface of the body of sleeve member 72 may be formed with anchoring protrusions 78, such as but not limited to, teeth or barbs or other similar elements. The anchoring protrusions 78 may protrude non-perpendicularly from the outer surface of the body of sleeve member 72.

Conical head portion 14 is received in countersunk aperture 74 of sleeve member 72. As similarly described hereinabove, tightening nut element 32 causes connector element to advance generally in the direction of arrow 34, thereby fixedly wedging head portion 14 in countersunk aperture 74 and sleeve member 72 in aperture (hole) 40 of planar element 28, and fixedly squeezing head portion 14 against elongate element 26. This forms a secure connection between elongate element 26 and planar element 28. Sleeve member 72 acts as an anchoring bolt and protective washer for the connection to planar element 28.

In the embodiment of FIG. 6, the planar element 28 may be a wall of a room or building, or any other structure. The anchoring protrusions 78 may “bite”, wedge or grab into the wall at aperture (hole) 40, which may be a hole in a plasterboard wall, for example, to provide safe anchoring of structures. The embodiment of FIG. 6 may be used to attach rods, poles, racks and many other structures to walls of bathrooms, showers, dining rooms, kitchens and many other applications.

It will be appreciated by persons skilled in the art that the present invention is not limited by what has been particularly shown and described hereinabove. Rather the scope of the present invention includes both combinations and subcombinations of the features described hereinabove as well as modifications and variations thereof which would occur to a person of skill in the art upon reading the foregoing description and which are not in the prior art.

What is claimed is:

1. A fastening system comprising:
a connector element comprising a conical head portion from which extends a threaded shank, a hole being formed through said head portion and said shank, said head portion being resiliently squeezable in a generally radially inwards direction, said hole being adapted for an elongate element to passes therethrough;
a sleeve member formed with a countersunk aperture, an outer surface of said sleeve member being formed with anchoring protrusions; and
a threaded nut element threadedly fastened to said threaded shank, wherein tightening of said threaded nut element moves and wedges said conical head portion against said countersunk aperture and squeezes said head portion radially inwards.

2. The fastening system according to claim 1, wherein said anchoring protrusions protrude non-perpendicularly from the outer surface of said sleeve member.

3. The fastening system according to claim 1, wherein one face of said sleeve member comprises a rim with an outer diameter greater than that of a body of said sleeve member.

4. The fastening system according to claim 1, further comprising an elongate element that passes through said hole, wherein tightening of said threaded nut element moves and wedges said conical head portion against said countersunk aperture and squeezes said head portion radially inward against said elongate element.

5. The fastening system according to claim 1, wherein said sleeve member is received in a hole formed in a planar element.

6. The fastening system according to claim 5, wherein said anchoring protrusions anchor against the hole formed in the planar element.

7. The fastening system according to claim 1, wherein said head portion is formed with slits that define petal portions, said petal portions being resiliently squeezable in a generally radially inwards direction.

8. The fastening system according to claim 1, wherein said connector element is formed with at least one lengthwise axial cut extending from a periphery of said head portion and said shank at least partially through to said hole.
